(19) United States
(12) Patent Application Publication
(10) Pub. No.: US 2013/0094656 A1
(43) Pub. Date: Apr. 18, 2013

(54) Intelligent Audio Volume Control for Robot

(71) Applicant: Hei Tao Fung, Fremont, CA (US)

(72) Inventor: Hei Tao Fung, Fremont, CA (US)

(21) Appl. No.: 13/274,345

(22) Filed: Oct. 16, 2011

(51) Int. Cl. H03G 3/20

(52) U.S. Cl. 381/57; 901/47

(57) ABSTRACT

A method for automatic audio volume control on a robot is presented. The robot can deliver its audio output at a comfortable and intelligible level to the user according to user's distance and background noise intensity in user's environment. The user's distance is estimated, by using a camera with known focal length and resolution, by using a stereo camera with known focal length and distance between lenses, or by using an electronic ranging device. Background noise intensity is measured by using a microphone and digital signal processing techniques. The audio output volume is adjusted considering the effect of signal attenuation over user's distance and the effect of background noise. The audio output volume adjustment mechanism can be close-looped, based on the measured signal to noise ratio of acoustic echo of the audio output.

### FIELD OF THE INVENTION

The present invention relates to intelligently controlling the audio volume of a robot that can interact with users.

### BACKGROUND

There have been many publications about automatic audio volume control. For example, Johnston talks about providing audio compensation within some frequency bands based on intensity of background noise. Ding et. al. use ultrasound ranging device to determine listener's distance and adjust audio volume accordingly. The method disclosed herein focuses on an audio volume control method for a robot that is capable of interacting with users through its audio and visual devices. By user herein we mean a person who listens to the robot and even talks to the robot. The robot speaking to a user too loud causes annoyance while speaking too softly creates intelligibility problem. For example, in a crowd, the robot may speak loud, whereas in a quiet room, the robot can speak softly. In an open space, it depends. Speaking to a person down the hall the robot may turn up the volume. Speaking to a nearby person in a hall, the robot may speak loud enough but not too loud lest other people in the hall are annoyed. The alternatives of using manual audio volume control are less attractive. For example, even given the tool to adjust the robot audio volume manually, users may not be adequately trained, and users may not feel convenient. As another example, while a remote user is doing videoconferencing via a robot with a user local to the robot, the remote user may not be able to tell whether the robot audio volume is appropriate. In this invention, we present a method that enables automatic audio volume control on the robot considering the local user environment.

### SUMMARY OF THE INVENTION

The object of this invention is enabling a robot to intelligently control its audio volume according to the local user's environment.

According to the recommendations from the American National Standards Institute (ANSI) and the Acoustical Society of America (ASA), a speaker's voice should reach a listener at no less than +15 dB signal to noise ratio for good speech intelligibility. In this invention, when the robot talks to a user the robot intermittently assesses the user's environment. Specifically, the robot estimates the user's distance from the robot and measures the background noise intensity. The robot increases the audio volume as the background noise intensity increases to maintain the proper signal to noise ratio. Also, audio signals attenuate by 6 dB travelling twice the distance. Therefore, the robot increases its audio volume by 6 dB when the user's distance from the robot is doubled.

There are multiple techniques for a robot to measure user's distance. A simple one assumes a camera mounted on the robot. Assuming a user's head is of a certain size, we can estimate the user's distance by the size of the user's head on an image. The second technique uses a stereo camera on the robot to capture a pair of images of the same user from different angles, involving epipolar geometry calculations. The third technique uses ranging devices such as laser distance meters, sonar distance meters, and radar distance meters.

Background noise generally refers to noise of a lower amplitude that persists for longer, while intermittent noise refers to higher-amplitude noise that lasts for only a short time (on the order of seconds). Background noise may undermine the intelligibility of the robot audio output. The robot may boost its audio volume by the same number of decibels to compensate for the background noise in the user's environment after estimating the background noise intensity in decibels. The robot, equipped with a microphone, captures the audio signals in the user's environment constantly and assesses the background noise intensity.

The robot audio volume is adjusted according to the user's distance and the background noise intensity. For example, in a controlled environment with no background noise, we find out that a typical user hears well and comfortably at d feet away from a robot when the audio output intensity is a dB. Now let's assume that in the actual deployment the background noise is b dB evenly in user's environment, and the user is D feet away. The robot audio output intensity is then adjusted to (a+b+6 log₂(D/d)) dB. We can calibrate for each design of robots for the set of a and d values before the deployment of the robots. Then adjust the audio volume according to measurements of b and D as described.

In this invention, we further present a close-looped audio volume control technique. The technique involves finding out in real time whether the audio volume adjustment is effective. The robot uses its microphone to capture audio signal in user's environment while there is audio output from the robot. The acoustic echo signal is therefore captured, i.e., the sound of the audio output from the robot, along with background noise and other sound, enters the microphone of the robot. In a typical teleconferencing application, acoustic echo cancellation is applied. If the robot has to do acoustic echo cancellation, then before doing that the robot may calculate the signal to noise ratio of the acoustic echo signal of its audio output. The robot may automatically adjust the audio volume so as to make the signal to noise ratio of the acoustic echo signal to be no less than a threshold, say, A dB. Then for a user of distance D feet away, adjust the audio volume to make the signal to noise ratio of the acoustic echo signal to be (A+6 log₂D) dB.

A robot that interacts with multiple users may need to understand the context of audio output delivery further. For example, in a conference setting, the robot should account for the user farthest away. In the case that the robot needs to deliver individual audio output one by one to users at different distances, the robot needs to quickly adjust its audio volume for each user.

For a semi-autonomous robot that facilitates videoconferencing between local users and remote users, the users determine the context of the audio output delivery and input the context to the robot manually. Alternatively, the robot may assume the user near the center of its field of vision to be the intended recipient of its audio output.

### BRIEF DESCRIPTION OF THE DRAWINGS/FIGURES

The present invention will be understood more fully from the detailed description that follows and from the accompanying drawings, which however, should not be taken to limit the disclosed subject matter to the specific embodiments shown, but are for explanation and understanding only.

FIG. 1 illustrates an embodiment of the invention disclosed.

FIG. 2 illustrates another embodiment of the invention disclosed.

FIG. 3 illustrates the principle behind the distance estimation using an image.

FIG. 4 illustrates the principle behind the distance estimation using a stereo camera.

FIG. 5 illustrates the idea of acoustic echo.

### DETAILED DESCRIPTION OF THE INVENTION

The object of this invention is enabling a robot to intelligently control its audio volume according to the local user's environment.

According to the recommendations from the American National Standards Institute (ANSI) and the Acoustical Society of America (ASA), a speaker's voice should reach a listener at no less than +15 dB signal to noise ratio for good speech intelligibility. A signal to noise ratio for speech intelligibility speech and aural comfort is between 15 dB and 30 dB. Not only background noise intensity affects speech intelligibility but also the distance that the audio output signal needs to travel to reach the user does. In this invention, when the robot talks to a user the robot intermittently assesses the user's environment. Specifically, the robot estimates the user's distance from the robot and measures the background noise intensity. The robot increases the audio volume as the background noise intensity increases to maintain the proper signal to noise ratio. Also, audio signals attenuate by 6 dB travelling twice the distance. Therefore, the robot increases its audio volume by 6 dB when the user is twice farther away.

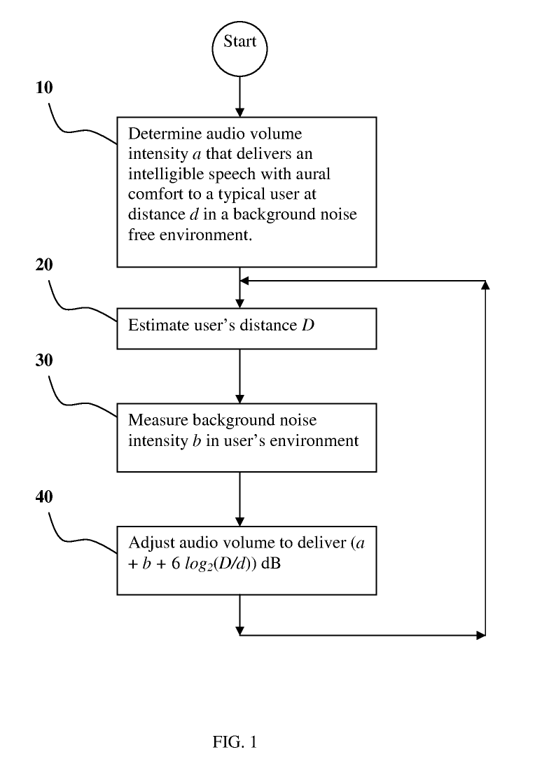

One embodiment of the method disclosed is illustrated in FIG. 1. It starts by calibrating the audio volume parameters for a robot, as in step 10. In a controlled environment with no background noise, we are to find out the audio output intensity a dB that a typical user hears well and comfortably at d feet away from the robot. At a distance of 3 feet, the loudness of a voice usually measures approximately 60 dB. In a private office the background noise is typically between 30 dB and 40 dB, according to Kerry Gardiner and John Malcolm Harrington, “Occupational Hygiene,” 2005, pp. 235-236, Blackwell Publishing, U.K. Therefore, for d being 3 feet, a typical value of a is between 20 dB and 30 dB. In step 20, the robot is to estimate the user's distance D feet. In step 30, the robot is to measure the background noise intensity b DB. In step 40, the robot adjusts its audio output intensity to be (a+b+6 log₂(D/d)) dB. Then the robot reassesses the measurements periodically.

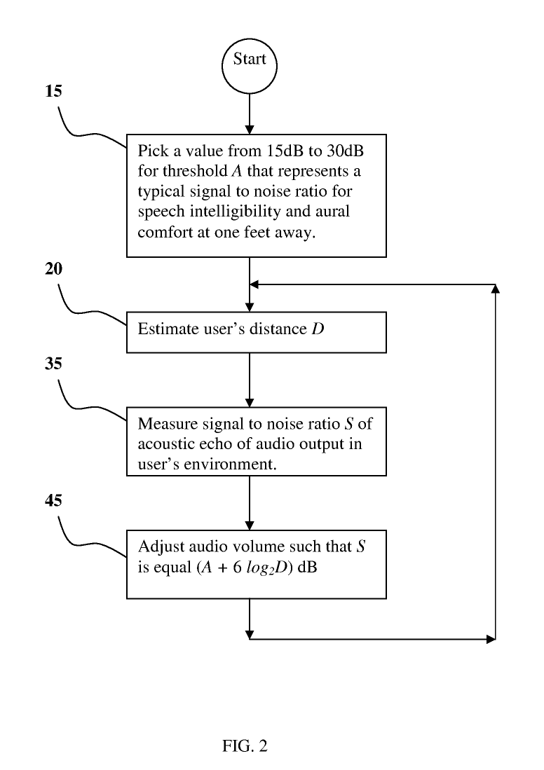

The disadvantage of the embodiment of FIG. 1 is that there is no feedback into the robot to assess the effects of the automatic audio volume control. Another embodiment of the method disclosed is illustrated in FIG. 2. The key difference is in step 35 that the robot captures the acoustic echo of the audio output and calculates the signal to noise ratio of the acoustic echo. The measurement of signal to noise ratio of the acoustic echo helps assess the effects of the automatic audio volume control. Furthermore, in step 45, the robot adjusts its audio output intensity such that the signal to noise ratio of the acoustic echo of the audio output is (A+6 log₂D) dB. The formulae in step 40 and in step 45 are very similar. The speaker of the robot and the microphone of the robot are assumed to be 1 feet away, so the parameter d is dropped off from the formula in step 45. The threshold A, as in step 15, is a value selected between 15 dB and 30 dB, that is the signal to noise ratio for speech intelligibility and aural comfort. Because the adjustment in step 45 is based on signal to noise ratio, the factor of background noise intensity has been accounted for. Due to the similarity of the formulae, the procedures in FIG. 1 and FIG. 2 can co-exist on the same robot, and the robot may use the average of the results of both techniques.

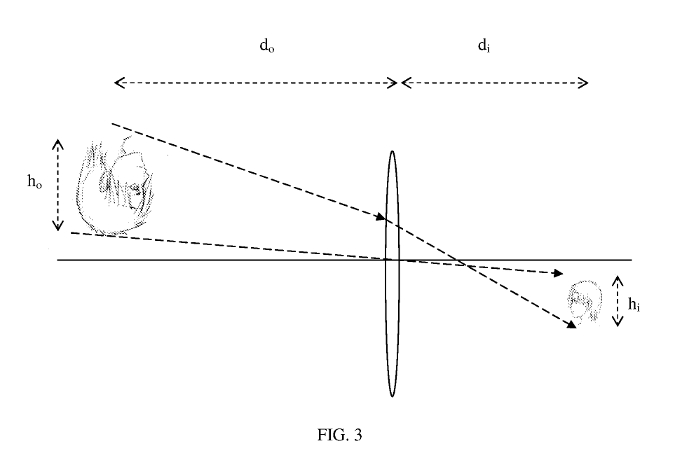

There are multiple techniques for a robot to measure user's distance in step 20. A simple one assumes a camera mounted on the robot. The geometry of a single lens camera is illustrated in FIG. 3. The relationship among the object size hₒ, the image size hᵢ, the object distance dₒ, and the image distance dᵢ is as follows:

dₒ=dᵢ×hₒ÷+hᵢ

When the object distance, which is the user's distance that we are interested in, is much larger than twice the focal length f of the lens, dᵢ is approximately equal to f. Assume an average user's head size; then hₒ is considered known. Knowing the camera resolution, we can obtain hᵢ based on the camera resolution and the number of pixels corresponding to the user's head on the image. The camera resolution is usually represented in pixels per inch. The unit can be converted into pixels per feet. Multiplying the number of pixels by the camera resolution yields hᵢ in feet. Therefore, the estimated user's distance D is the product of the focal length f and an average head size hₒ divided by the size of the user's head in the image hᵢ. The camera may have zooming capability. The zooming can be implemented by changing the focal length (usually being the combined focal length of a set of lenses) or by changing the image resolution via image processing techniques. As long as the focal length and the image resolution are known, the user's distance estimation technique described is applicable.

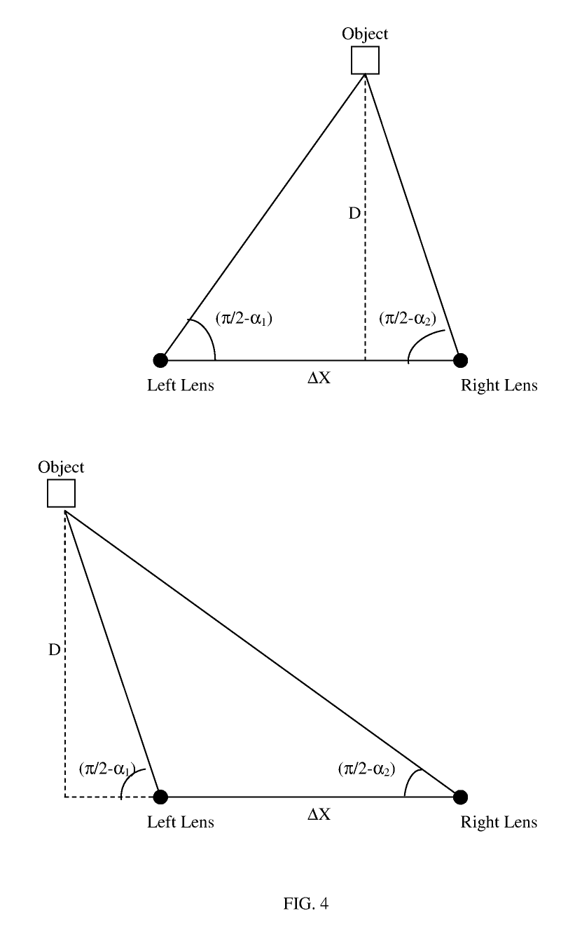

The second technique assumes a stereo camera on the robot. The stereo camera consists of two lenses and is able to capture a pair of images of the same user from different angles, as illustrated in FIG. 4. We may leverage the work of Edwin Tjandranegara, “Distance Estimation Algorithm for Stereo Pair Images,” 2005, pp. 1-6, Purdue e-Pubs, U.S.A. For simplicity, we can assume the stereo camera has identical lenses, and more importantly, the diameter of the camera's field stop S and the focal length of the lens f are known. In the case that an object is located between the two lenses:

Ø=tan⁻¹ (S/2f)

α₁=tan⁻¹((P₁−N₁/2)/(N₁/2)×tan Ø), where Pᵢ is the pixel location of the object in the left image and Nᵢ is the total number of pixels in the left image.

α₂=tan⁻¹((N₂/2−P₂)/(N₂/2)×tan Ø), where P₂ is the pixel location of the object in the right image and N₂ is the total number of pixels in the right image.

D=(tan(n/2−α₁)×tan(π/2−α₂)×ΔX)/(tan(n/2−α₁)+tan(π/2−α₂)), where ΔX is the distance between the lenses.

In the case that an object is located to the left of both lenses:

Ø=tan⁻¹ (S/2f)

α₁=tan⁻¹((Nᵢ/2−P₁)/(N₁/2)×tan Ø), where P₁ is the pixel location of the object in the left image and N₁ is the total number of pixels in the left image.

α₂=tan⁻¹((N₂/2−P₂)/(N₂/2)×tan Ø), where P₂ is the pixel location of the object in the right image and N₂ is the total number of pixels in the right image.

D=(sin(π/2−α₁)×sin(π/2−α₂)×ΔX)/(sin(α₂−α₁)), where ΔX is the distance between the lenses.

In an image, the user image region is composed of many pixels as a person has a number of body parts. The technique requires identifying the pixels in the pair of images that represent the same part of the user. Applying the formulae described, the distance D of a specific part of the user is obtained. The same calculation can be applied to a number of parts of the user so as to obtain a number of distance estimates. The average value of the distance estimates can be used as the estimated distance of user.

The third technique uses ranging devices such as laser distance meters, sonar distance meters, and radar distance meters. The theory of operations of those devices is well known.

Which distance estimation techniques to use is mostly a cost decision. A robot that interacts with users is usually equipped with at least one camera, and perhaps a stereo camera or a ranging device for autonomous navigation.

Step 30 and step 35 involve measurement of background noise. Background noise generally refers to noise of a lower amplitude that persists for longer, while intermittent noise refers to higher-amplitude noise that lasts for only a short time (on the order of seconds). Background noise may undermine the intelligibility of the robot audio output. We assume that the robot cannot remove the background noise in user's environment local to the robot although the robot may apply well-known digital signal processing techniques to reduce the background noise intrinsic to its audio output. The robot, however, may boost its audio volume by the same number of decibels to compensate for the background noise in the user's environment after estimating the background noise intensity in decibels. That technique assumes that the background noise is evenly intense in the space between the user and the robot. The robot, equipped with a microphone, captures the audio signals in the user's environment constantly and calculates the noise intensity or signal to noise ratio via digital audio processing techniques.

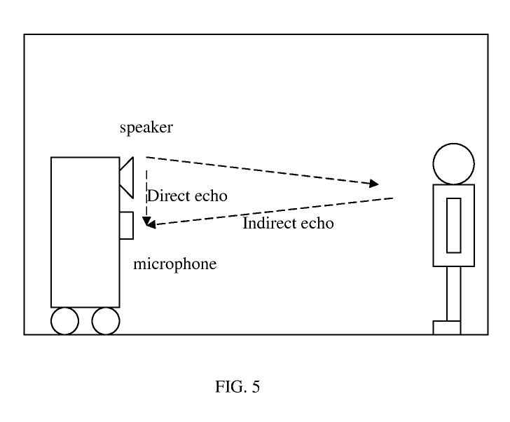

The technique described in FIG. 2 provides a close-loop or feedback mechanism to assess the effect of automatic audio volume control via capturing acoustic echo of the audio output. FIG. 5 illustrates the concept of acoustic echo. There is direct acoustic echo, which is the sound coming out from the speaker into the microphone directly. There is indirect acoustic echo. The sound bounces off a hard surface, such as a wall or a ceiling, before reaching the microphone. That early indirect acoustic echo may actually help intelligibility if it is received within tens of milliseconds after the direct acoustic echo. However, the late acoustic echo, which is the sound bounced off a plurality of hard surfaces before reaching the microphone, is usually turned into reverberation that undermines intelligibility if it is intense enough. The intensity of the indirect acoustic echo depends on the acoustic characteristics of the user's environment. There is an advantage of the technique in FIG. 2 over the technique in FIG. 1. The audio output of the speaker reaching the microphone, the audio output of the speaker reaching the user's ear, and the user's voice reaching the microphone are all subject to the same acoustic characteristics of the user's environment. Therefore, by measuring the signal to noise ratio of the acoustic echo of the audio output and adjusting the audio volume accordingly, the factor of acoustic echo intensity to user is cancelled out, and the user's should experience the same level of audio output intelligibility and aural comfort resulting from the intelligent audio volume control regardless of the user's distance from the robot.

A robot that interacts with multiple users may need to understand the context of audio output delivery further. For example, in a conference setting, the robot should account for the user farthest away because the audio output is meant for all users in the conference. In a reception hall setting, the robot may need to deliver individual audio output one by one to users at different distances, the robot needs to quickly adjust its audio volume for each user. For a semi-autonomous robot that facilitates videoconferencing between local users and remote users, the users may determine the context of the audio output delivery and input the context to the robot manually. Alternatively, it would be desirable that the robot assesses the context of the audio output delivery via artificial intelligence. For example, the robot may assume the user near the center of its field of vision to be the intended recipient of its audio output.

The embodiments described above are illustrative examples and it should not be construed that the present invention is limited to these particular embodiments. Thus, various changes and modifications may be effected by one skilled in the art without departing from the spirit or scope of the invention as defined in the appended claims.

1. A method for intelligent audio volume control on a robot, comprising:
(a) estimating the distance of a user from said robot;
(b) measuring background noise intensity;
(c) automatically adjusting audio volume of said robot according to the measurements of user's distance and background noise intensity; and
(d) from time to time automatically adjusting audio volume of said robot according to the new measurements of user's distance and background noise intensity.

2. The method as in claim 1, wherein estimating user's distance from said robot is based on an image of said user from one camera of said robot.

3. The method as in claim 2, wherein estimating user's distance from said robot is based on parameters comprising:
(a) size of the user's head in the image captured by said robot;
(b) focal length of the camera of said robot; and
(c) image resolution of the camera of said robot.

4. The method as in claim 3, wherein said focal length or said image resolution of the camera of the robot may vary by zooming.

5. The method as in claim 1, wherein estimating user's distance from said robot is based on a pair of images of said user from a stereo camera of said robot.

6. The method as in claim 5, wherein estimating user's distance from said robot is based on parameters comprising:
(a) the distance between the lenses of said stereo camera of said robot; and
(b) the focal length of the lenses of said stereo cameras of said robot.

7. The method as in claim 1, wherein estimating user's distance from said robot is making use of an electronic distance measuring device.

8. The method as in claim 7, wherein said electronic distance measuring device is a laser distance meter.

9. The method as in claim 7, wherein said electronic distance measuring device is a sonar distance meter.

10. The method as in claim 1, wherein the audio volume is controlled to be higher when the user is farther away from said robot.

11. The method as in claim 1, wherein the audio volume is increased by 6 dB when user's distance from said robot is doubled.

12. The method as in claim 1, wherein the audio volume is controlled to be higher when the background noise intensity is higher.

13. The method as in claim 1, wherein the audio volume is increased by the same number of decibels as the background noise intensity increases.

14. The method as in claim 1, wherein the audio volume is controlled in such a manner that the signal to noise ratio of the acoustic echo relative to the background noise is adjusted to a value according to user's distance from said robot.

15. The method as in claim 1, wherein there may be a plurality of users.

16. The method as in claim 15, wherein audio volume is controlled accounting for the user farthest away from said robot.

17. The method as in claim 15, wherein audio volume is controlled considering the user in the center of the field of vision of said robot to be the target audience.

18. The method as in claim 15, wherein audio volume is controlled considering the context of the audio output delivery.

19. A device capable of automatically adjusting audio output volume, comprising:
(a) a means for estimating user's distance;
(b) a means for measuring background noise intensity; and
(c) a means for increasing audio output volume as user's distance increases or background noise intensity increases.

20. The device as in claim 19, wherein said means for estimating user's distance is a camera with known focal length and resolution.

21. The device as in claim 19, wherein said means for estimating user's distance is a stereo camera with known focal length and distance between the lenses.
